(19) United States
(12) Patent Application Publication
(10) Pub. No.: US 2026/0258577 A1
(43) Pub. Date: Sep. 3, 2026

(54) METHODS FOR SYNTHESIZING III-V NANOCRYSTALS

(71) Applicant: THE UNIVERSITY OF CHICAGO, Chicago, IL (US)

(72) Inventors: Wooje Cho, Chicago, IL (US); Dmitri V. Talapin, La Grange Park, IL (US)

(21) Appl. No.: 18/881,891

(22) PCT Filed: Aug. 21, 2023
(86) PCT No.: PCT/US2023/072541

§ 371 Date: Jan. 7, 2025

Related U.S. Application Data
(60) Provisional application No. 63/399,788, filed on Aug. 22, 2022.

(51) Int. Cl. C30B 7/10; C30B 29/40

(52) U.S. Cl. CPC C30B 7/105; C30B 29/403; C30B 29/406

(57) ABSTRACT

Provided are methods for synthesizing III-V nanocrystals. In embodiments, such a method comprises exposing a biphasic mixture comprising a molten salt phase and an organic liquid phase to a group V precursor comprising a group V element under conditions to form a III-V compound in the form of nanocrystals, wherein the molten salt phase comprises a group III precursor comprising a group III element, and the organic liquid phase comprises an organic solvent.

### CROSS-REFERENCE TO RELATED APPLICATIONS

The present application claims priority to U.S. provisional patent application No. 63/399,788 that was filed Aug. 22, 2022, the entire contents of which are incorporated herein by reference.

### REFERENCE TO GOVERNMENT RIGHTS

This invention was made with government support under grant number 2004880 awarded by the National Science Foundation. The government has certain rights in the invention.

### BACKGROUND

Gallium nitride (GaN) is a key semiconductor material for blue light-emitting diodes, lasers, and high-power and high-frequency electronic devices owing to its wide band gap, chemical stability, high breakdown electric field, and high electron saturation velocity. Aluminum nitride (AlN) is a related nitride material with intriguing properties such as an unusually strong ionicity of chemical bonds, a large free energy of formation, a wide 6.0 eV bandgap, high thermal conductivity, and piezoelectricity. Owing to these characteristics, AlN is used in optoelectronic devices, high-power electronics, and microelectromechanical systems. As AlN and GaN are isostructural, they can form solid solutions (i.e., AlₓGa₁₋ₓN) and important heterostructures such as quantum wells have been prepared with this materials system.

### SUMMARY

Provided are methods for synthesizing III-V nanocrystals. In embodiments, such a method comprises exposing a biphasic mixture comprising a molten salt phase and an organic liquid phase to a group V precursor comprising a group V element under conditions to form a III-V compound in the form of nanocrystals, wherein the molten salt phase comprises a group III precursor comprising a group III element, and the organic liquid phase comprises an organic solvent.

Other principal features and advantages of the disclosure will become apparent to those skilled in the art upon review of the following drawings, the detailed description, and the appended claims.

### BRIEF DESCRIPTION OF THE DRAWINGS

Illustrative embodiments of the disclosure will hereafter be described with reference to the accompanying drawings.

FIG. 1A is the reaction scheme for exposing MX₃ to NH₃ at 290° C. in trioctylamine/hexadecylamine (TOA/HDA) solution, at relatively low concentrations of MX₃ (0.2 M or less) to produce amorphous products FIG. 1B shows a powder X-ray diffraction (PXRD) pattern measured from the products of reaction between 0.2 M GaCl₃ and excess NH₃ in TOA/HDA solution. The vertical lines show the positions and relative intensities for bulk zinc-blende (ZB, lines top) and wurtzite (WZ, lines bottom) GaN phases. Major peaks are indexed. FIG. 1C shows the atomic pair distribution function (PDF) measured for the products of the reaction between 0.2 M GaCl₃ and excess NH₃ in TOA/HDA solution. The experimental data is shown along with the simulated PDF of a 1 nm wurtzite GaN nanocrystal (inset structure). FIGS. 1D-1E show PDFs of AlN nanocrystals from 0.1 M AlBr₃ and NH₃ in TOA/HDA solution. Inset structures represent the structures used for simulations. The experimental PDF of AlN is compared to the simulated PDF from a 1 nm-diameter spherical WZ AlN nanocrystal in FIG. 1D. FIG. 1E shows a similar comparison but with simulated PDF from a molecular 4-membered-ring AlN structure. FIG. 1F shows PXRD patterns of products made using various MX₃ and concentrations.

FIG. 2A is the reaction scheme for exposing MX₃ to NH₃ at 290° C. in trioctylamine/hexadecylamine (TOA/HDA) solution, at relatively high concentrations of MX₃ (1 M) to produce crystalline products (nanocrystals) FIG. 2B shows PXRD patterns of GaN nanoparticles synthesized from GaCl₃, GaBr₃, and GaI₃ with reference lines from wurtzite (WZ, lines bottom) and zincblende (ZB, lines top) bulk GaN phases. Major peaks are indexed. FIG. 2C shows PXRD pattern of AlN nanorods synthesized from AlBr₃ with reference lines from WZ AlN phase. Major peaks are indexed. FIG. 2D shows a TEM image of WZ GaN nanorods and nanotetrapods synthesized using GaCl₃. The inset shows a high-resolution image with the structure of the nanotetrapods indicated with dashed lines. FIG. 2D shows a TEM image of ZB GaN nanocrystals synthesized using GaI₃. The inset shows a high-resolution image with the structure of the nanocrystals indicated with dashed lines. FIG. 2F shows a TEM image of AlN nanorods. The inset shows a high-resolution image with the structure of the nanorods indicated with dashed lines.

FIGS. 3A-3C show simulated PXRD patterns for different GaN and AlN nanomaterials: (FIG. 3A) WZ GaN nanorod with 2-nm diameter and 9-nm length, (FIG. 3B) Spherical ZB GaN nanocrystal with 4-nm diameter, and (FIG. 3C) WZ AlN nanorod with 3-nm diameter and 9-nm length.

FIGS. 4A-4C illustrate how molten salt facilitates solution synthesis of crystalline III-nitride nanocrystals. FIG. 4A schematically depicts microscopic reversibility during synthesis of II-VI and III-nitride nanocrystals. FIG. 4B illustrates the free energy landscape for the elementary step of breaking Ga—N bonds required for establishing microscopic reversibility in organic solvent. FIG. 4C shows that a highly polarizable molten salt medium can lower the activation energy for chemical bond breaking.

FIGS. 5A-5G show results from the synthesis of GaN nanorods using high-pressure ammonia. FIG. 5A shows absorption spectra of GaN nanorods produced using different ammonia pressures. Small artifacts between 250-270 nm are from trace amounts of residual toluene. FIG. 5B shows PXRD spectra of GaN nanorods produced using different ammonia pressures. Vertical lines on the bottom are WZ GaN reference. Major peaks are indexed. FIG. 5C shows a TEM image of GaN nanostructures from high-pressure (5 MPa) ammonia synthesis. Nanotetrapods and nanorods coexist. Inset shows a high-resolution TEM image of a GaN nanorod. FIG. 5D shows photoluminescence (PL) and photoluminescence excitation (PLE) spectra of GaN nanorods from synthesis with 5 MPa ammonia. Arrows indicate the monitored emission wavelengths of PLE spectra of corresponding colors. The PLE spectra indicate that populations of thicker nanorods emit from midgap states of lower energy. Simulated PXRD patterns of nanorods with different diameters are shown in FIG. 5E and for different numbers of stacking faults, in FIG. 5F. FIG. 5G shows a PDF pattern of GaN nanocrystals synthesized with ammonia at 5 MPa.

FIG. 6 is a plot showing the parameter space accessible for traditional solution synthesis compared to the conditions for chemical vapor deposition (CVD) and bulk crystal growth of GaN semiconductors.

FIG. 7 is a schematic illustration of the high-pressure setup used in some embodiments of the present methods.

FIG. 8 shows the shift in the photoluminescence at room temperature (RT) as compared to low temperature (LT) from GaN nanocrystals synthesized with ammonia at 5 mPa.

### DETAILED DESCRIPTION

Provided are methods for synthesizing III-V nanocrystals. The methods comprise exposing a biphasic mixture comprising (or consisting of) a molten salt phase and an organic liquid phase to a group V precursor comprising a group V element. The molten salt phase comprises (or consists of) a group III precursor comprising a group III element while the organic liquid phase comprises (or consists of) an organic solvent. The exposure is carried out under conditions to produce III-V nanocrystals, which may be recovered from the biphasic mixture. This includes conditions which induce covalent bond formation between the group III element and the group V element to form a III-V compound, as well as conditions which allow for microscopic reversibility, i.e., the breaking and reforming of such bonds to allow for atomic rearrangements and thus, crystalline (versus amorphous) growth. As demonstrated in the Example, below, the present methods are based, at least in part, on the serendipitous finding that use of the molten salt phase enables microscopic reversibility at moderate temperatures to achieve highly crystalline III-V nanostructures in solution.

As noted above, the molten salt phase in the biphasic mixture comprises (or consists of) the group III precursor. The group III precursor is a chemical compound (versus a group III element) comprising the group III element, e.g., B, Al, Ga, In, or Tl. In embodiments, the group III element is Al or Ga. Desirably, the group III precursor (and the molten salt phase) does not comprise oxygen. In embodiments, the group III precursor does not comprise carbon and hydrogen. In embodiments, the group III precursor does not comprise a group V element. Similarly, the molten salt phase may be free of carbon, hydrogen, and a group V element (this does not preclude the presence of carbon, hydrogen, and a group V element in the biphasic mixture that originates from the organic liquid phase and/or the group V precursor).

The group III precursor may be a molten inorganic salt. The molten inorganic salt which may have a melting point (Tm) below the temperature being used in the present methods, e.g., below 350° C. This includes having a Tm in a range of from above room temperature (about 20 to 25° C.) to less than 350° C., from 50° C. to less than 300° C., from 65° C. to 275° C., from 80° C. to 200° C., and from 95° C. to 150° C. Group III molten inorganic salts include group III halides, i.e., MX₃, wherein M is the group III element and X is a halide, e.g., Cl, Br, or I. Group III molten inorganic salts also include those having formula AMX₄, wherein A is an alkali metal, e.g., Li, Na, K, or Cs, M is the group III element, and X is the halide.

A single type of group III precursor (e.g., molten inorganic salt) or multiple, different types of group III precursors may be used. The term “type” as used herein refers to chemical formula such that a single type means the same chemical formula and different type means different chemical formula.

The following group III precursors may be excluded, in embodiments, polymeric gallium imide ((Ga(NH)_{3/2})ₙ), group III azides (Et₂Ga(N₃), (N₃)₂Ga[(CH₂)₃NMe₂], (Et₃N)Ga(N₃)₃), group III acetates, group III amidos (Ga₂[N(CH₃)]₆, group III cupferrons.

In embodiments, a group III molten inorganic salt (or a combination thereof) alone provides the molten salt phase. However, in other embodiments, other components may be included in the molten salt phase, including other salts (or eutectic mixtures thereof). For example, the molten salt phase may comprise (or consist of) both MX₃ (also the group III precursor) and AX, wherein X is the halide and A is selected from Li, Na, K, and Cs.

The organic liquid phase in the biphasic mixture comprises (or consists of) the organic solvent. The organic solvent is an organic chemical compound comprising carbon and hydrogen, although it may comprise heteroatoms, e.g., N. However, desirably, the organic solvent (and the organic liquid phase) does not comprise oxygen. In addition, the organic solvent desirably has a relatively high boiling point (Tb), e.g., greater than 100° C., greater than 150° C., or greater than 200° C. The organic solvent (and the organic liquid phase) may exhibit some ability to solubilize the selected molten salt phase (or components thereof) at the temperature being used in the present methods, but not so much to prevent the formation of the biphasic mixture as further described below.

The organic solvent may be an alkylamine. The alkyl group(s) in the alkylamine may have at least 4 carbons, at least 6 carbons, or at least 8 carbons. This includes a range between any of these values and a range of from 4 to 26, from 6 to 24, and from 8 to 22. The alkyl group(s) may be linear alkyl groups. Illustrative alkylamines include tertiary alkylamines, e.g., trioctylamine (TOA). Alkylamines also include primary alkylamines, e.g., hexadecylamine (HDA), and secondary alkylamines, e.g., dioctylamine.

A single type of organic solvent or multiple, different types organic solvents may be used. In embodiments, an organic solvent (or a combination thereof) alone provides the organic liquid phase. However, in other embodiments, other components may be included in the organic liquid phase. In embodiments, no reducing agent, e.g., n-butyllithium, is used in the organic liquid phase or the biphasic mixture.

The molten salt phase and the organic liquid phase (and thus the biphasic mixture) are liquids at the temperature being used in the present methods. The term “biphasic” is used in reference to the immiscibility of the selected molten salt phase and the organic liquid phase (including at the temperature being used in the present methods), or in reference to use of an amount of the group III precursor that exceeds the solubility of the group III precursor in the selected organic liquid phase (including at the temperature being used in the present methods), or both. As noted above, however, the molten salt phase and the organic liquid phase need not be perfectly immiscible. As described in the Example below, formation of the biphasic mixture may be confirmed visually from the presence of two distinct phases (generally absent mixing) or an emulsion (generally using mixing). As with the molten salt phase and the organic liquid phase, the biphasic mixture itself is desirably free of oxygen.

It is to be understood that at an initial time point in the present methods, e.g., upon initial exposure of the biphasic mixture to the group V precursor, the biphasic mixture does not comprise any III-V nanocrystals. In addition, the biphasic mixture being used in the present methods is generally free of pre-synthesized III-V nanocrystals, including III-V nanocrystals which may have been synthesized using other methods.

The present methods involve exposing the biphasic mixture to the group V precursor. The group V precursor may be chemical compound comprising the group V element, e.g., N, P, As, Sb, or Bi. In embodiments, the group V element is N. The group V precursor is distinct from the group III precursor, i.e., they are different chemical entities. Desirably, the group V precursor does not comprise oxygen. In embodiments, the group III precursor does not comprise carbon. The group V precursor may be a pnictogen hydride, e.g., ammonia (NH₃), or its conjugate base, e.g., sodium amide (NaNH₂). Unlike the molten salt phase and the organic liquid phase, the group V precursor may be in its gaseous phase at the temperature being used in the present methods. A single type of group V precursor or multiple, different types of group V precursors may be used. The following group V precursors may be excluded, in embodiments: P(TMS)₃, alkali nitrides (Li₃N), hexamethyl disilazane, As(NMe₂)₃, lithium bis(trimethylsilyl amide).

The conditions used to carry out the present methods include parameters such as selection of materials (molten salt phase, organic liquid phase, group V precursor), amounts thereof, and temperature. As noted above, in general, these parameters are tuned to facilitate nucleation, growth, and microscopic reversibility of a desired III-V nanocrystal. Further guidance for selection of materials has been described above.

Regarding temperature, generally the temperature is below a temperature at which the selected organic liquid phase (or components thereof) decomposes, but above the Tm of the selected molten salt phase (or components thereof). Illustrative temperatures include those within a range of from greater than room temperature to less than 400° C., from 75° C. to 350° C., or from 100° C. to 300° C.

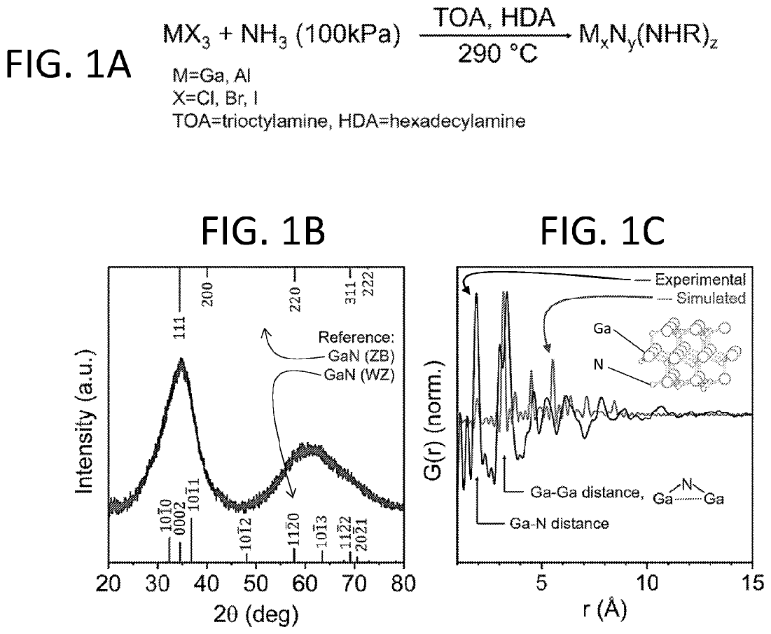

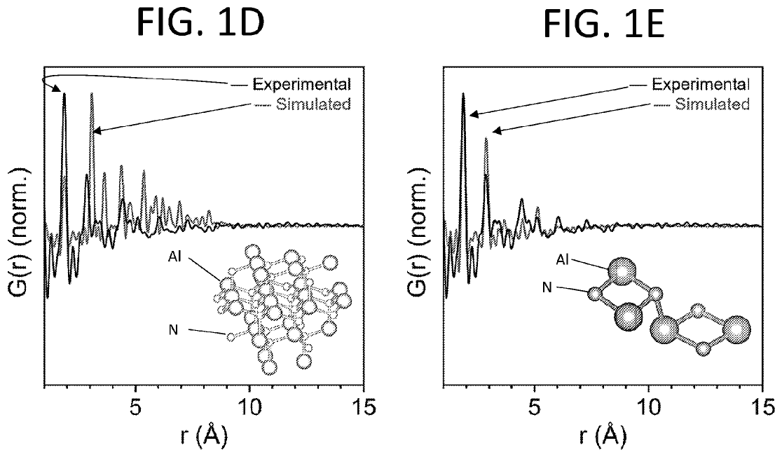

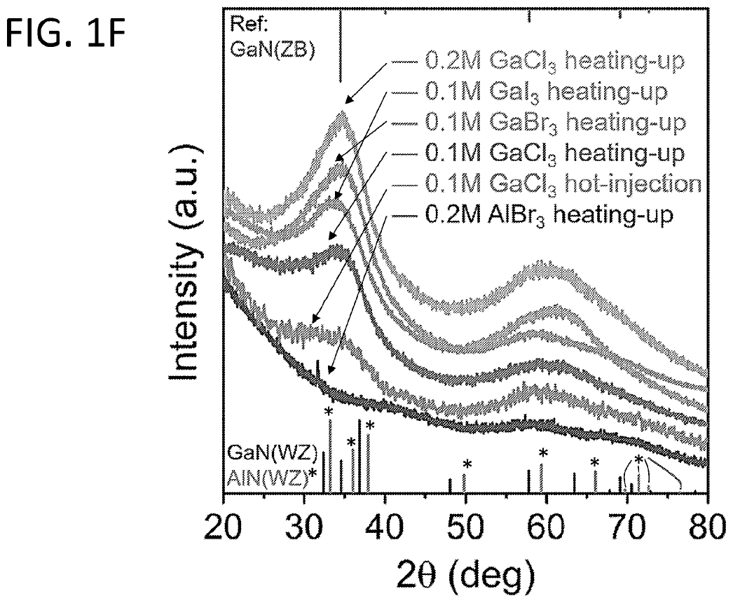

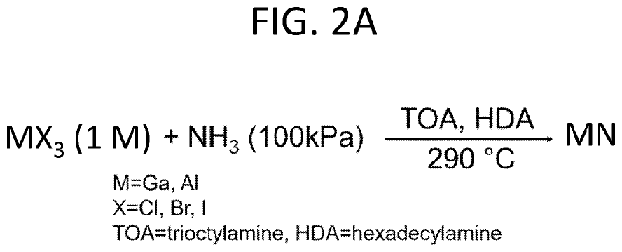

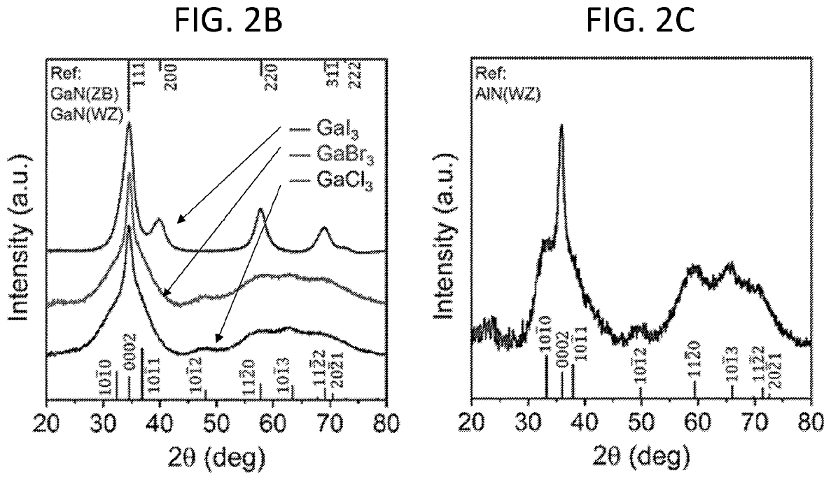

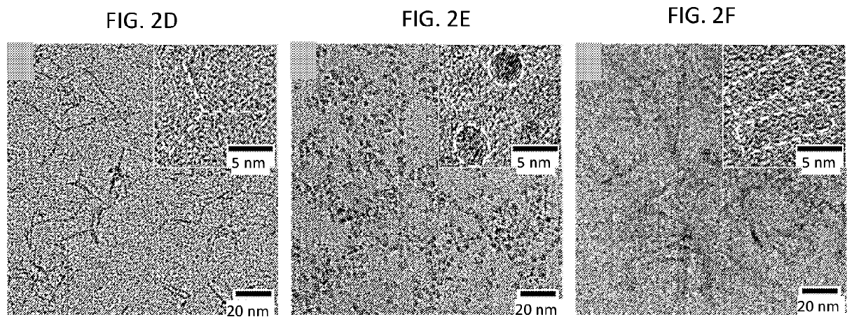

Regarding amounts, the group III precursor may be present in the biphasic mixture at a concentration of at least 0.3 M, at least 0.5 M, at least 0.8 M, or at least 1 M. This includes a range between any of these values, as well as a range of from 0.5 M to 15 M, from 1 M to 10 M, and from 2 M to 5 M. These amounts encompass embodiments in which the group III precursor(s) alone provides the molten salt phase. As demonstrated in the Example, below, embodiments of the present methods make use of relatively high concentrations of the group III precursor to ensure nanocrystal formation (versus amorphous products). (Compare FIGS. 1A-1F to 2A-2F.) The relatively high concentrations further ensure the formation of the biphasic mixture as noted above. The organic liquid phase may make up at least 90 weight %, at least 95 weight %, at least 98 weight % (but less than 100 weight %) of the biphasic mixture. This includes a range between any of these values, as well as a range of from 90 weight % to 99 weight %. By “weight %” it is meant (weight of the organic liquid phase)/(total weight of biphasic mixture)*100. For gaseous group V precursors, a pressure in a range of from atmospheric pressure (about 0.1 MPa) to 10 MPa, from 0.1 MPa to 8 MPa, or from 1 MPa to 5 MPa may be used. As demonstrated in the Example, below, embodiments of the present methods make use of relatively high pressures of NH₃ to improve the crystallinity of III-nitride nanocrystals as well as to increase nanocrystal size (e.g., diameter). Conditions may also include ensuring the absence of O₂/air as the steps of the method are carried out.

The III-V nanocrystals produced by the present methods may be characterized by their composition, which depends upon the selected group III precursor(s) and group V precursor(s). In embodiments, the III-V nanocrystals are binary III-V nanocrystals, i.e., having a single type of III element and a single type of V element. However, the III-V nanocrystals are not limited to binary III-V nanocrystals, e.g., as multiple, different types of group III precursors may be used, e.g., to provide ternary III-V nanocrystals. In embodiments the III-V nanocrystals are GaN nanocrystals, AlN nanocrystals, AlₓGa₁₋ₓN nanocrystals, or combinations thereof. (In AlₓGa₁₋ₓN nanocrystals, the ratios of Al and Ga may vary, e.g., x=0.01 to 0.99.) The III-V nanocrystals are generally free of oxygen, which may be confirmed using elemental analysis and/or X-ray diffraction analysis as described in the Example, below.

The III-V nanocrystals may be further characterized by their size and shape. Regarding size, the largest cross-sectional dimension of the nanocrystals is not greater than 1000 nm and is generally significantly smaller, e.g., no greater than 100 nm, no greater than 50 nm, no greater than 25 nm, or no greater than 10 nm. This includes largest cross-sectional dimensions in a range of from 1 nm to 50 nm, from 1 nm to 25 nm, and from 1 nm to 10 nm. These dimensions may refer to the average largest cross-sectional dimension for a collection of nanocrystals. The nanocrystals may also be referred to a quantum dots (QDs). Regarding shape, the nanocrystal shape may be, e.g., spherical, cubic, elongated (e.g., nanorods), or branched (e.g., nanotetrapods). For any of these shapes, the dimensions above may refer to a diameter of the nanocrystal or a diameter of a branch thereof. A plurality of nanocrystals may all have the same shape or the nanocrystals may include those of different shapes. As noted above and demonstrated in the Example, below, the conditions being used in the present methods, e.g., type of group III precursor, amount of group V precursor (e.g., NH₃ pressure), may also be selected to achieve a desired nanocrystal size and shape.

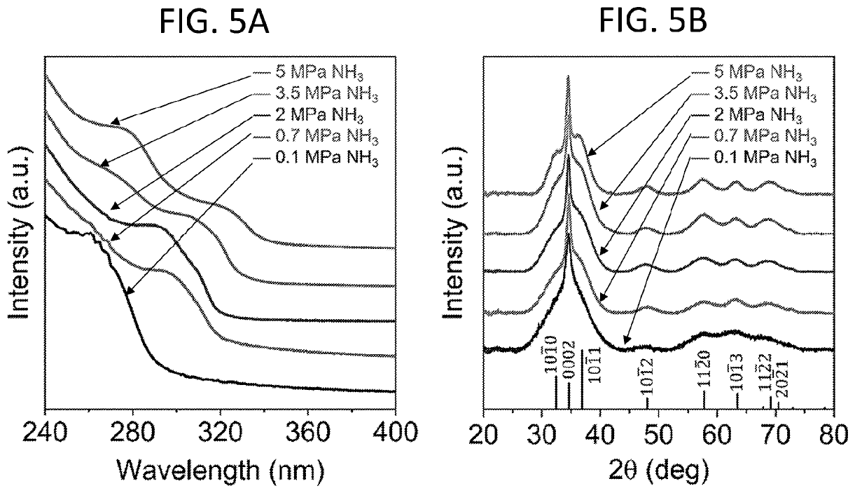

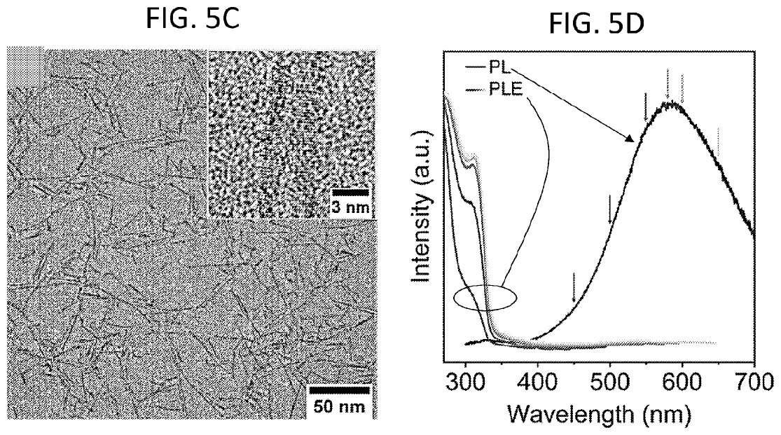

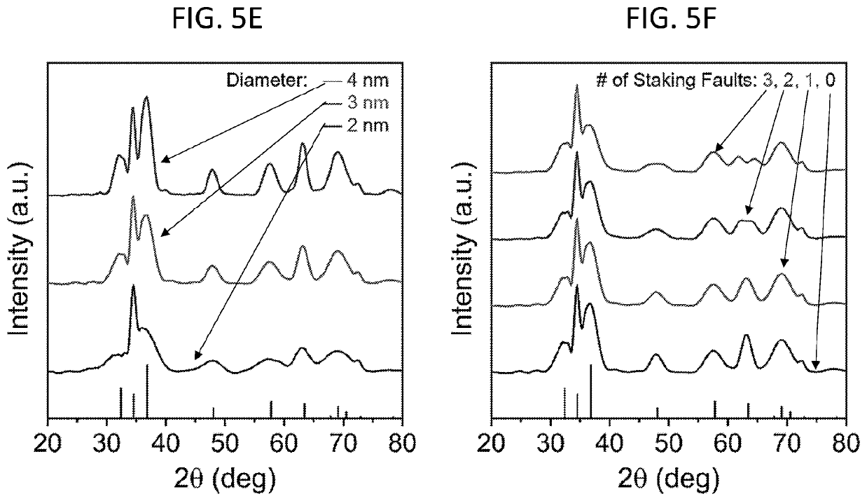

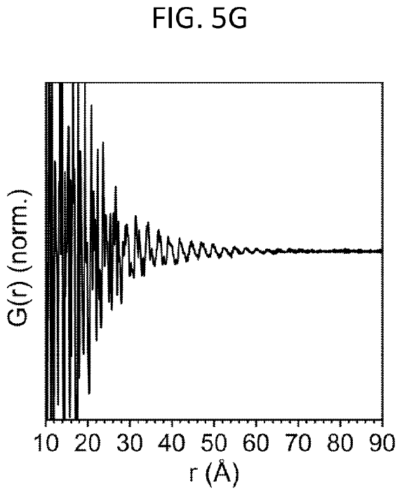

As is clear from the term “nanocrystals,” the III-V nanocrystals are crystalline in nature, i.e., the III and V atoms are arranged in an ordered lattice, by contrast to amorphous materials exhibiting a lack of such atomic ordering. Crystallinity may be confirmed and quantified using X-ray diffraction analysis as described in the Example, below. III-V nanocrystals formed using the present methods exhibit powder XRD (PXRD) spectra such as those shown in FIGS. 2B, 2C, 5B. These PXRD spectra include sharp peaks matching those in expected crystalline phases for the selected III-V semiconductor compound. This is by contrast to FIGS. 1B and 1F showing PXRD spectra from amorphous III-V products. These PXRD spectra include only broad peaks or lack any peaks. Pair distribution function (PDF) measurements as described in the Example, below, may also be used to confirm and quantify crystallinity. III-V nanocrystals formed using the present methods exhibit PDF spectra well-matched to simulated PDF spectra and may further exhibit long-range oscillations (see FIG. 5G). This is by contrast to FIGS. 1C-1E showing PDF spectra from amorphous III-V products. These PDF spectra show little overlap between measured and simulated results and lack long-range oscillations. As noted above and demonstrated in the Example, below, the conditions being used in the present methods, e.g., amount of group V precursor (e.g., NH₃ pressure), may also be selected to improve crystallinity.

Related to the properties of the III-V nanocrystals described above, is the ability of the nanocrystals to form a colloid, i.e., a homogenous and uniform dispersion of the nanocrystals within a continuous phase, e.g., in a non-polar solvent such an n-hexane, methylcyclohexane, etc. This includes the ability of the nanocrystals to form colloids in molten media as described in U.S. Pat. Nos. 11,040,323 and 11,247,914, each of which is hereby incorporated by reference in its entirety. Organic capping ligands, e.g., oleylamine, oleic acid, etc., may be included in forming the colloids, but may not be necessary if molten media is used as the continuous phase. Again, as demonstrated in the Example, below, the ability to form colloids is by contrast to amorphous III-V products, which cannot form colloids.

The present methods need not, but may include other steps. For example, the III-V nanocrystals may be recovered from the biphasic mixture and, if desired, redispersed as a colloid. Illustrative details for such recovery are provided in the Example, below. As another example, shells may be grown over the III-V nanocrystals. Illustrative shell-growth techniques are described in U.S. Pat. Nos. 11,040,323 and 11,247,914, each of which is hereby incorporated by reference in its entirety. However, the methods need not include additional steps (e.g., annealing) to achieve III-V nanocrystals having the high crystalline quality as described above.

The III-V nanocrystals synthesized using the present methods may be used in a variety of applications, e.g., optoelectronic devices, high-power electronics, and microelectromechanical systems. The III-V nanocrystals themselves are also encompassed by the present disclosure.

### Example

### Introduction

Colloidal semiconductor nanocrystals, also called quantum dots, can demonstrate unique optical and electronic properties due to the quantum confinement effects enabling fine-tuning of electronic structure via size and shape engineering. Colloidal nanomaterials also offer a way to incorporate semiconductors into non-epitaxial device stacks using inexpensive solution-based processing. Despite many desirable properties of III-nitride materials, little work has been published on solution synthesis of colloidal GaN and AlN nanocrystals.

To date, a traditional colloidal nanoparticle synthesis, via controlled nucleation and growth from molecular precursors in solution phase, has been unable to produce GaN and AlN nanocrystals with structural perfection or control of other key parameters (size, size distribution, etc.). The challenges relate to the need for microscopic reversibility of monomer addition in order to grow crystalline particles. Irreversible formation of chemical bonds during crystal growth means that the bonds cannot be rearranged after they are formed. The inability to disassemble and reorganize incorrectly bonded fragments, which are inevitable during deposition, prevents formation of perfect crystals, so syntheses lacking microscopic reversibility result in amorphous rather than crystalline reaction products. To illustrate, the bond dissociation energies (BDEs) for Ga—N, Al—N, Cd—Se, and In—P bonds are 240 kJ/mol, 268 kJ/mol, 128 kJ/mol, and 198 kJ/mol, respectively. (See Lide, D. R., CRC Handbook of Chemistry and Physics. 87th Edition ed.; CRC Press: 2006 and Kandalam, A. K., et al; The Journal of Physical Chemistry B 2000, 104 (18), 4361-4367.) Since GaN and AlN consist of substantially stronger bonds than, e.g., CdSe or InP, growth of crystalline GaN and AlN is significantly more challenging.

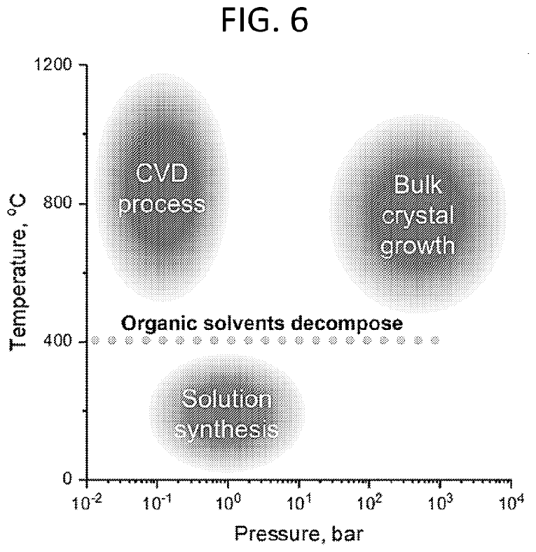

Moreover, a simple comparison of the optimized conditions for CVD and bulk crystal growth of GaN and AlN to the parameter space accessible for traditional colloidal synthesis (see FIG. 6) further illustrates the challenges in solution synthesis of GaN and AlN nanocrystals. Specifically, most CVD processes for GaN and AlN growth happen in the 400-1000° C. temperature range. Other growth techniques for bulk GaN and AlN crystals require both high temperature and high pressure, e.g., 400-850° C., and 100-500 MPa have been used in ammonothermal syntheses. Solution synthesis, however, typically uses high-boiling organic solvents that chemically decompose above 400° C. Furthermore, typical laboratory glassware cannot access the pressure range previously identified suitable for growth of high quality GaN crystals. These limitations have, thus far, thwarted controllable solution synthesis of crystalline III-nitride materials.

However, this Example demonstrates a unique approach to synthesizing crystalline colloidal GaN and AlN nanocrystals by using a molten salt phase together with a high-boiling organic solvent. Notably, the presence of the molten salt phase helps the III-nitride system achieve microscopic reversibility at temperatures consistent with traditional colloidal synthesis. As described further below, GaN nanotetrapods, GaN nanorods, GaN nanospheres, and AlN nanorods were all prepared under mild conditions and exhibited good colloidal stability in an organic solvent. Additionally, the Example shows that control of ammonia pressure over the range 0.1-5 MPa allowed for tuning of the diameter of GaN nanorods.

### Experimental Details

### Chemicals

Aluminum bromide (AlBr₃, Alfa Aesar, ultra dry, 99.999%), ethanol (Sigma-Aldrich, 200 proof, anhydrous, ≥99.5%), n-hexane (Sigma-Aldrich, anhydrous, 95%), gallium bromide (GaBr₃, Alfa Aesar, ultra dry, 99.998%), gallium chloride (GaCl₃, Alfa Aesar, ultra dry, 99.999%), gallium iodide (GaI₃, Alfa Aesar, ultra dry, powder, 99.999%), methanol (Sigma-Aldrich, anhydrous, 99.8%), methylcyclohexane (Sigma-Aldrich, anhydrous, ≥99%), potassium chloride (KCl, Alfa Aesar, ultra dry, 99.95%), toluene (Sigma-Aldrich, anhydrous, 99.8%) were stored under inert atmosphere and used as received. Potassium tetrachlorogallate (KGaCl₄) was prepared by melting a stoichiometric mixture of GaCl₃ and KCl under nitrogen. Oleic acid (Sigma-Aldrich, technical grade, 90%), olelyamine (Sigma-Aldrich, technical grade, 70%), and stearic acid (Fluka, 97%) were dried under vacuum at 100° C. for 3 hours and stored under nitrogen. Trioctyalamine (TOA, Sigma-Aldrich, 98%) and hexadecylamine (had, Sigma-Aldrich, technical grade, 90%) were vacuum distilled over sodium (Sigma-Aldrich, 99.8%) and stored under nitrogen. Since it is solid at room temperature, HDA was heated gently to melt it before use. Ammonia gas (Airgas, anhydrous grade) was distilled over sodium (Sigma-Aldrich, 99.8%) in a dry-ice bath right before use for ambient-pressure syntheses. For high-pressure syntheses, the same ammonia gas was condensed inside a high-pressure vessel. Details about high-pressure setups are described below.

### Synthesis of Gallium Oxynitride

A solution of gallium stearate was prepared by degassing 0.5 mmol GaCl₃ and 1.5 mmol of stearic acid in 5 mL of TOA at 90° C. for 3 hours under vacuum with vigorous stirring. After degassing, the solution of gallium stearate was heated to 290° C. under nitrogen. Excess ammonia was passed over this mixture for 5 minutes. The reaction mixture was then heated for one hour at 290° C. After the reaction, the reaction mixture was cooled down to room temperature by removing the heat source. The gallium oxynitride produced was non-colloidal and was separated from the mixture by centrifugation. The obtained solid was washed with toluene, ethanol, and methanol a few times each.

### Synthesis of Amorphous GaN and AlN

In a nitrogen atmosphere, 0.5-1 mmol of gallium or aluminum halide was fully dissolved in 4 mL of TOA. To this mixture, 0.6 g of HDA was added. For heating-up syntheses, the mixture was heated to 290° C. under ammonia flow with vigorous stirring. Alternatively, for hot-injection synthesis, the mixture was heated to 290° C. under nitrogen, and then ammonia was passed over the solution for 5 minutes. In both cases, the reaction mixture was heated afterward for 1 hour at 290° C. The reaction mixture was cooled to room temperature by removing the heat source. White solids precipitated from the reaction mixture upon cooling. This solid was separated from the solution by centrifugation and was washed with 10 mL of toluene a few times for removal of excess organic molecules. The remaining solids were washed with 40 mL of methanol a few times to remove ammonium halide byproducts of the reaction.

Synthesis of Crystalline GaN and AlN with Ambient Pressure Ammonia

In nitrogen atmosphere, 5 mmol of finely ground gallium or aluminum halide salt was mixed with 4 mL of TOA and 0.6 g of HDA. In a typical heat-up synthesis, the mixture was heated to 290° C. under ammonia flow with vigorous stirring. For the KGaCl₄ control experiment, the reaction mixture was first heated to 290° C., and then ammonia was passed over the solution for 5 minutes. After 1 hour of heating at 290° C., the heat source was removed and the reaction mixture was cooled to room temperature. The product spontaneously precipitated from the reaction mixture. This solid was separated with centrifugation and washed first with 10 mL of toluene and then with 40 mL of methanol a few times each to remove excess organics and salt byproducts. To extract colloidal particles from the solid, the solid was sonicated for 30 minutes with the mixture of 16 mL of n-hexane (or toluene), 2 mL of oleylamine, and 2 mL of oleic acid. A solution of nanoparticles was separated with centrifugation from the non-colloidal solid. From this solution, nanoparticles could be flocculated with ethanol. Particles were washed a few times with ethanol before finally being dispersed in methylcyclohexane or n-hexane for measurements.

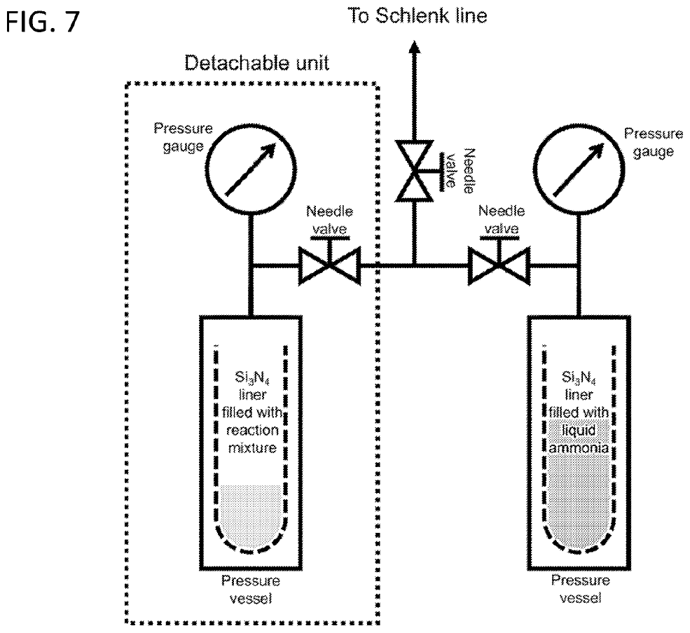

### High-Pressure Setup (FIG. 7)

Two identical high-pressure vessels from Parr Instrument Company (Series 4740, 75 mL) were used for the setup. A tee with three needle valves was set to connect two vessels and a Schlenk line, which was necessary to operate the system air-freely. To one fully evacuated vessel, liquid ammonia was condensed by using an ice/water bath. The other detachable vessel, equipped with a silicon nitride liner and a needle valve, was loaded with a reaction mixture in a nitrogen glovebox. While the needle valve was closed, the detachable vessel was brought out of the glovebox and assembled to the system. After assembly, any part that was open to air should be evacuated. Two heating tapes were installed to heat two vessels separately. During the operation, the liquid-ammonia vessel was heated mildly, and the reaction vessel was heated to a high temperature with a thermal insulation. Caution! Pressure of ammonia can be high enough to break glassware, so handle needle valves carefully not to flow high-pressure ammonia to a Schlenk line.

### Synthesis of GaN Under High-Pressure Ammonia

In the reaction vessel, 5 mmol of finely ground KGaCl₄, 4 mL of TOA, and 0.6 g of HDA were loaded together with a glass stirbar under nitrogen atmosphere. After the reaction vessel was assembled to the system, two pressure vessels were heated separately; the one with the reaction mixture was heated to 290° C. under ambient pressure nitrogen with vigorous stirring, while the other with liquid ammonia was heated gently to a pressure about 2-3 MPa higher than the target pressure. To the heated reaction mixture, desired pressure (0.7, 2, 3.5, or 5 MPa) of hot ammonia gas was transferred by manipulating two needle valves between two pressure vessels. During this process, the needle valve toward the Schlenk line should be closed. After 1 hour of reaction, pressured gas in the reaction vessel was detached from the system and slowly vented in a fume hood until the pressure reached 1 MPa, a pressure high enough to prevent back flow of air into the vessel during venting and low enough to avoid a condensation of liquid ammonia during cooling. The reaction vessel was cooled to room temperature and transferred into a nitrogen atmosphere. The reaction product was washed with toluene and methanol a few times each. Colloidal solutions from this product were obtained by sonication of solid product with 16 mL of n-hexane (or toluene), 2 mL of oleylamine, and 2 mL of oleic acid. Nanoparticles were flocculated with ethanol from this solution, collected with centrifugation, and dispersed in methylcyclohexane or n-hexane for the measurements.

### Characterization Techniques

Transmission electron microscopy (TEM). TEM images were obtained with a 300 kV FEI Tecnai G2 F30 microscope. Samples were prepared by drying colloidal solutions diluted in toluene on Ted Pella pure carbon film grids. After drying the solutions, grids were washed gently with ethanol and dried under vacuum.

Optical spectra. Colloidal samples were gently washed with ethanol to remove excess organic ligands and the original solvent, and then were redispersed as dilute solutions in methylcyclohexane. Absorption spectra of these solution samples were taken with a Shimadzu UV-3600 Plus spectrophotometer from 220 nm to 700 nm. Photoluminescence (PL) and photoluminescence excitation (PLE) spectra of solution samples were taken with a Horiba Jobin Yvon FluoroMax-4. PL spectra at low temperature (77K) were also taken with a Horiba Jobin Yvon FluoroMax-4 accompanied with a Dewar add-on filled with liquid nitrogen.

Powder X-ray diffraction (PXRD). PXRD patterns were obtained with a Rigaku MiniFlex with a Cu Kα source. Samples were prepared by drying concentrated colloidal solutions on zero-diffraction silicon grids (Rigaku 906165 Flush, Si510).

Pair distribution function (PDF) measurement. PDF data was collected from the beam line 11-ID-B of Advanced Photon Source (APS) at Argonne National Laboratory (ANL). Total scattering data were acquired as images on a large flat panel detector. GSAS-II software was used to reduce 2-D diffraction images to 1-D diffraction patterns. Masks were drawn and integration processes were carried out using the software. Pair distribution functions were extracted from 1-D diffraction patterns with scaling Q-range of 20.782-23.091.

### Simulation Details

### Powder X-Ray Diffraction (PXRD) Simulations

Powder X-ray diffraction patterns were simulated from structures built using the Atomsk software package. Briefly, GaN nanorods with different sizes were prepared by first generating a large GaN supercell and then using a cylindrical cutoff oriented parallel to the c-axis to prepare cylindrical nanorods. Atomic structures were visualized using the VESTA software package. X-ray diffraction patterns were simulated using the DebyeByPy software package which calculates intensities (I) as a function of the scattering length vector (q) in units of Å⁻¹ were calculated using the Debye formula:

$$I ( q ) = {\sum }_{i} {\sum }_{j} {f}_{i} ( q ) {f}_{j} ( q ) \frac{sin ( {qr}_{ij} )}{{r}_{ij}}$$

where the sums are over all of the atom pairs, f is the angle-dependent scattering factor calculated from Hartree-Fock wavefunctions by Cromer and Mann, and r is the distance between atoms in Å. The simulated data were plotted against 2θ (2θ=2 arcsin (λq/4π)), where λ is wavelength of the X-ray source.

### Pair Distribution Function (PDF) Simulations

Simulated pair distribution functions were obtained from conversion of simulated PXRD patterns. PXRD patterns were obtained from the method above in the q range of (0.25] Å⁻¹ and converted into PDFs with the program PDFgetX3 in the xPDFsuite package.

### Result and Discussion

General considerations for synthesis of GaN and AlN by solution reactions. Presenting another challenge in the solution synthesis of GaN and AlN nanocrystals is the high oxophilicity of Ga(III) and Al(III), which creates problems for synthesis of oxygen-free nanocrystals. For example, gallium precursors containing Ga—O bonds can induce oxygen doping of GaN phase during the reaction. For example, reported powder X-ray diffraction (PXRD) patterns for GaN nanocrystals synthesized from gallium cupferron and stearate precursors showed a small peak at ~43° which is not a characteristic for either the wurtzite or zincblende gallium nitride phases. (Sardar, K., et al; Advanced Materials 2004, 16 (5), 425-429 and Choi, Y. C., et al; Chemistry of Materials 2019, 31 (15), 5370-5375.) As a control experiment, it was found that the reaction of gallium stearate with dry, oxygen-free ammonia in trioctylamine solvent at 290° C. resulted in a gallium oxynitride spinel (Ga_{2.81}O_{3.57}N_{0.43}) rather than GaN (data not shown). Thus, metal precursors used for GaN synthesis desirably should not contain Ga—O bonds. Similarly, metal precursors used for AlN synthesis also desirably should not contain Al—O bonds, as aluminum makes an even stronger bond with oxygen than gallium (the BDE for Ga—O is 374 kJ/mol, while for Al—O it is 502 kJ/mol). (Lide, D. R., CRC Handbook of Chemistry and Physics. 87th Edition ed.; CRC Press: 2006.) Therefore, to avoid inclusion of oxygen impurities in GaN and AlN nanostructures, this Example made use of oxygen-free precursors, solvents, and other components of the reaction mixture. Specifically, such oxygen-free conditions were realized by using metal halides, ammonia, and amines.

As shown in FIG. 1A, the products of reactions between MX₃ (M=Ga, Al; X=Cl, Br, I) and NH₃ in trialkylamine solvent were first studied. In the heating-up approach, 0.1 M and 0.2 M solutions of MX₃ were dissolved in 4 mL of trioctylamine (TOA) and 0.6 g of hexadecylamine (HDA) was heated from room temperature to 290° C. under constant flow of ammonia. Alternatively, in a hot-injection approach, the MX₃ solution was pre-heated to 290° C. under dry nitrogen atmosphere, followed by a flow of ammonia into the reaction flask for 5 minutes. The reaction mixture was kept at 290° C. for one hour before cooling to room temperature. As-synthesized products in both approaches were non-colloidal at room temperature and could be separated from solution with centrifugation. The resulting white solids were washed with toluene to remove remaining alkylamines and then with methanol to remove ammonium halide, a major byproduct of these reactions. All the reaction products of GaX₃ precursors showed similar PXRD patterns with two broad features around 35° and 60° two theta angles (FIGS. 1B, IF). No obvious diffraction peaks were present in the PXRD pattern of a product from AlBr₃. These results all indicate the formation of an amorphous reaction product rather than a crystalline one.

To better understand the nature of the reaction products, atomic pair distribution function (PDF) analysis was carried out for the products formed by reacting 0.1 M or 0.2 M MX₃ (M=Ga, Al; X=Cl, Br, I) solutions with excess NH₃. FIGS. 1C-1E show the pair distribution function G(r) plots of the “GaN” (FIG. 1C) and “AlN” (FIGS. 1D-1F) reaction products as compared to the experimental data. For the GaCl₃+NH₃ reaction products, the interatomic distances for the first two G(r) peaks were close to the positions expected for crystalline GaN, but the peaks at larger distances significantly deviated from the interatomic distances in a GaN crystal. The first G(r) peak reflected Ga—N bonds, which was slightly shorter (1.90 Å) than the expected distance in GaN crystals (1.95 Å). The second G(r) peak reflected the nearest Ga . . . Ga distances, and these distances match well to the expected value in GaN crystals, which implies that Ga—N—Ga bond angles were close to 109.5°. The second peak split into two components, suggestive of two distinct bonding motifs. Moreover, the ratio of intensities for the first two G(r) peaks corresponding to Ga—N and Ga . . . Ga distances for the reaction product was significantly larger than the ratio for crystalline GaN. This discrepancy suggests that many nitrogen atoms forming Ga—N bonds do not participate in the bridging Ga—N—Ga bonding. A shorter Ga—N bond length, broader features from Ga . . . Ga correlations, and less intense peaks from longer-distance atomic pairs are all characteristics of amorphous GaN rather than crystalline GaN. Taken together, the PDF analysis establishes that the GaCl₃+NH₃ reaction product is an amorphous material consisting of distorted tetrahedral structures with numerous Ga vacancies and only locally resembles the tetrahedrally coordinated crystalline phase.

Based on the PDF analysis, AlBr₃+NH₃ reaction product has a totally different structure than its gallium counterpart. As shown in FIG. 1D, except for the first peak (Al—N bonds ~1.90 Å), all other G(r) features significantly deviated from those expected for AlN crystals. The AlBr₃+NH₃ reaction did not yield a product adopting any motif of the wurtzite (WZ) or zinc blende (ZB) structures. The second G(r) peak, corresponding to the nearest Al . . . Al distance (2.87 Å), significantly deviated from both the Al . . . Al distance in WZ or ZB AlN (3.08 Å). A rapid decay of G(r) amplitude also suggests formation of a low-dimensional structure with no long-range correlations. As shown in FIG. 1E, the PDF can best be described as arising from polymeric structures having Al₂N₂ four-membered rings. The Al—N—Al bond angle calculated from the positions of first two G(r) peaks was also consistent with this assignment.

The non-crystalline nature of MX₃+NH₃ reaction products can result from the irreversible binding of metal and nitrogen containing fragments with no subsequent rearrangements of subunits. However, as noted above, the formation of GaN and AlN crystals requires microscopically reversible binding of the atomic building blocks. Although high temperatures may achieve microscopic reversibility (e.g., as used in CVD synthesis), solution synthesis cannot arbitrarily increase reaction temperature due to solvent limitations.

Formation of crystalline GaN and AlN nanostructures in solution. It was found that crystalline GaN and AlN nanoparticles could be synthesized if the reaction mixture contained significantly larger amounts of metal halide precursor, nominally exceeding 1 M GaX₃ or AlX₃ in TOA and HDA (FIG. 2A). In a typical synthesis, 5 mmol of finely ground anhydrous metal halide salt was mixed with 4 mL of TOA and 0.6 g of HDA, and then ammonia was flowed over the mixture at room temperature followed by heating to 290° C. The reaction mixture was held at 290° C. for one hour and then cooled down to room temperature. The resulting III-nitride particles were not colloidal at this stage and were collected with centrifugation. The solid was washed first with toluene and then methanol to remove excess alkylamine and ammonium halide. These nanoparticles could then be colloidally stabilized in an n-hexane or toluene solution of oleylamine and oleic acid (10% v/v each) after brief sonication. The remaining non-colloidal part was removed by centrifugation, and nanoparticles in the supernatant were flocculated with ethanol followed by dispersion in fresh n-hexane to form a colloidal solution (images not shown). The whole process of synthesis and purification was conducted under inert atmosphere; this avoids oxygen inclusion as the III-nitride particles slowly lose colloidal stability upon exposure to air.

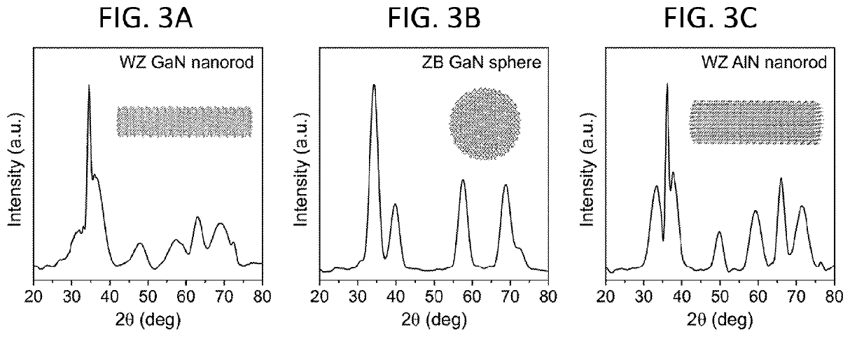

Gallium chloride and gallium bromide precursors yielded highly anisotropic WZ-phase GaN nanostructures, grown along the crystallographic direction, which included nanotetrapods and nanorods (FIG. 2B). Their PXRD patterns showed sharp peaks in agreement with simulated X-ray diffraction patterns for nanorods of GaN (FIGS. 2B, 3A). TEM images indicated that the products from reactions using gallium chloride had a higher proportion of nanotetrapods than those from gallium bromide reactions (FIG. 2D). TEM images also revealed that the product from gallium bromide reactions had tiny spherical nanocrystals, which were not observable in the PXRD patterns, mixed with the nanorods. When gallium iodide was used as precursor, spherical ZB-phase GaN nanocrystals formed instead of WZ GaN nanorods (FIGS. 2B, 2E). The Scherrer grain size of the spherical ZB GaN particles was about 4 nm and the PXRD pattern matched well with the simulated pattern (FIG. 3B).

PDF analysis was also performed for direct comparison with the amorphous GaN products (data not shown). Products from a reaction using 1 M gallium chloride appeared to have a greater amorphous component. PDFs of products from gallium bromide and gallium iodide reactions matched well with expected patterns from simulated nanocrystalline GaN in WZ and ZB phases, respectively. It is notable that PDFs of GaN nanocrystals from gallium bromide showed a regular oscillation up to 5 nm. This oscillation had a period of 0.26 nm, which is the distance between planes of WZ-GaN crystal, indicating nanocrystals anisotropically grown along direction.

The reaction of 1 M AlBr₃ with NH₃ produced WZ AlN nanorods grown along the direction, showing a sharp peak in PXRD, in line with the patterns observed for GaN nanorods (FIGS. 2C, 2F, 3C). This is believed to be the first example of colloidal crystalline AlN nanoparticles synthesized in solution. It was observed that the yield of AlN nanorods (i.e., nanocrystals) versus amorphous AlN byproduct was low.

The formation of crystalline GaN and AlN particles is surprising and counterintuitive because using the same MX₃ and NH₃ precursors yielded amorphous products when the halide salt was present at lower concentrations (FIGS. 1A-1F). Serendipitously, it was noticed that among the experimental runs producing crystalline versus amorphous products, the homogeneity of the reaction mixture differed. Specifically, crystalline particles formed when large amounts of GaX₃ or AlX₃ salts were used and when the halide salts were not fully dissolved in the TOA/HDA solvent before the reaction started. It was realized that due to low melting points of gallium and aluminum halides (77.9° C. for GaCl₃, 121.5° C. for GaBr₃, 212° C. for GaI₃, and 97.5° C. for AlBr₃), the reaction mixtures contained a molten inorganic salt phase that was immiscible with the organic phase. It is believed that this polar phase plays an important role in the formation of crystalline GaN and AlN phases as further discussed below.

The reaction between GaX₃ and NH₃ generated fine white solids of ammonium halide and III-nitride products that obscured direct observation of molten gallium halide droplets during the reaction. Therefore, another approach was used to prove whether the inhomogeneity observed was critical for the synthesis of crystalline particles or whether crystallization was simply induced by an increased salt concentration. While gallium chloride is soluble in the mixture of TOA and HDA at high temperature, potassium tetrachlorogallate (KGaCl₄) remains phase-separated from TOA/HDA mixtures at 250° C., which is above the melting point of the salt (images not shown). Specifically, visually, it was observed that the GaCl₃ mixture was a clear homogeneous solution while the KGaCl₄ mixture had a clear separation between an upper organic phase with white emulsion and a lower, clear molten salt phase. As discussed above, hot injection of excess ammonia into a homogeneous solution containing 1 mmol of GaCl₃ in 4 mL of TOA and 0.6 g of HDA pre-heated to 290° C. resulted in amorphous reaction products (FIG. 1F). However, the hot injection of excess ammonia into a biphasic mixture of 1 mmol of KGaCl₄, 4 mL of TOA, and 0.6 g of HDA at 290° C. resulted in a qualitatively different reaction product (data not shown). Specifically, a homogeneous solution of gallium chloride generated amorphous species, similar to those described in FIGS. 1A-1F, while the biphasic mixture of KGaCl₄ produced crystalline WZ-GaN nanorods, similar to those described in FIGS. 2A-2F and FIGS. 3A-3C. These results support the importance of the molten salt phase in generating crystalline III-nitride nanomaterials.

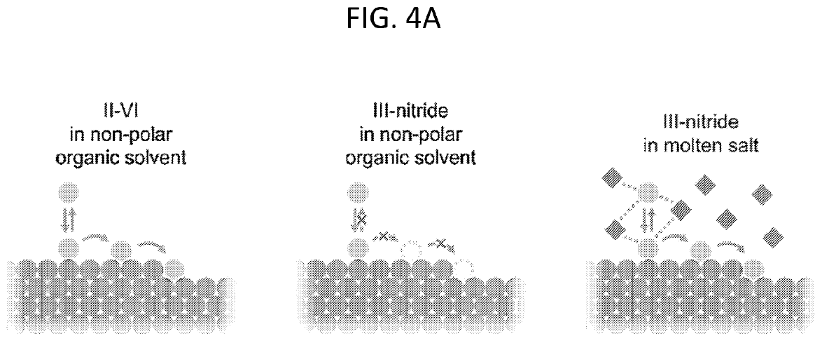

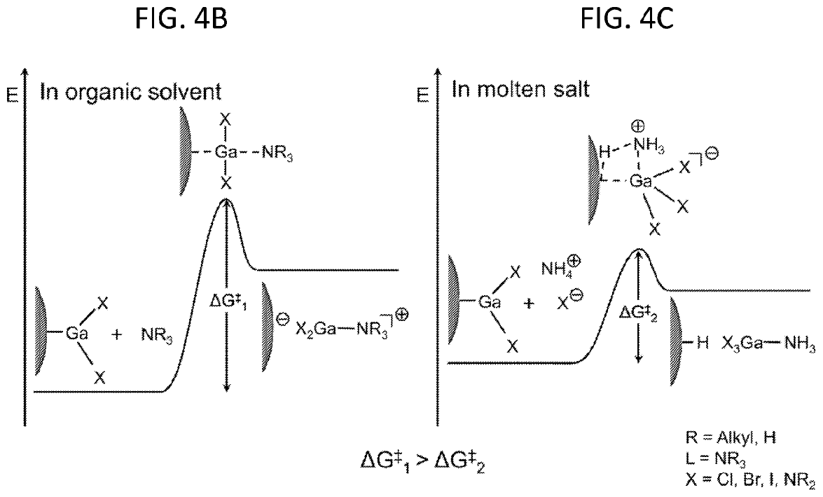

As noted above, microscopic reversibility during particle growth is essential to generate crystalline particles. FIG. 4A schematically illustrates monomer addition to a growing nanoparticle in different material systems. In a synthesis of II-VI (e.g., CdSe) nanocrystals, monomer additions are reversible due to relatively small chemical bond energy, and, therefore, the growth of perfect crystalline phase can occur at relatively low temperatures via reversible addition of atoms (FIG. 4A, left panel). Unlike II-VI semiconductors, GaN and AlN have strong bonds which impede efficient formation of crystalline products in organic solution (FIG. 4A, middle panel). However, the present results indicate that the presence of molten salts in the reaction mixture can restore the microscopic reversibility during nucleation and growth (FIG. 4A, right panel).

Without wishing to be bound to a particular theory, it is believed that the molten salt environment facilitates monomer detachment by efficiently stabilizing charged species. FIGS. 4B and 4C schematically depict possible pathways for surface atom detachment with cleavage of Ga—N bonds. For a typical ZB or WZ III-V nanocrystal terminated with thermodynamically stable low-index facets, surface metal atoms can be bonded to two X-type ligands, which can be represented as Z-type GaX₂ fragments. In non-polar organic solvents, charged species are energetically unfavorable and chemical species typically remain charge-neutral. A detachment of the surface Ga atom likely proceeds via L-promoted Z-type ligand displacement where nucleophilic L-type ligand (alkylamine) binds to the surface Ga atom and weakens its bonding with the crystal lattice (FIG. 4B). Such cleavage generates charged species, and the energy of the system is greatly increased. However, in a highly polarizable molten salt environment, charged species are present in large quantities. The removal of a Z-type GaX₂ group can be promoted by an X-type anion, followed by a proton transfer from an ammonium ion to a negatively charged surface nitrogen site (FIG. 4C). This process, nominally X-promoted Z-type ligand displacement, does not produce any highly unstable charged nor under-coordinated reaction products, and the energy change of the system is moderate. The detachment of misbound surface atoms can therefore occur more efficiently in molten salts as compared to non-polar organic solvents.

Solution synthesis of III-nitride nanostructures using high pressure ammonia. To test the effect of pressure on colloidal synthesis of III-nitride nanocrystals, a setup for running solution phase reactions under high-pressure ammonia gas was developed (see FIG. 7). Using this setup, a mixture of 5 mmol of KGaCl₄, 4 mL of TOA, and 0.6 g of HDA was pre-heated to 290° C. in a stainless-steel pressure vessel lined with silicon nitride. High-pressure ammonia at desired pressure was prepared by heating pre-dried liquid ammonia in a separate pressure vessel. The two pressure vessels were connected and high-pressure ammonia of 0.75, 2, 3.5, or 5 MPa was transferred to the reaction vessel. Similar to the ambient pressure GaN synthesis, after heating for one hour at 290° C., the vessels were cooled to room temperature. As an ambient-pressure (100 kPa) control, the reaction mixture of same amount of KGaCl₄, TOA, and HDA was pre-heated to 290° C., followed by a flow of ambient-pressure ammonia for 5 minutes. This mixture was also heated for one hour at 290° C. and then cooled to room temperature. In all cases, as-synthesized particles were non-colloidal and could be collected by centrifugation. Precipitates were washed first with toluene to remove excess alkylamines and then with methanol to remove salt by-products. A brief sonication with oleylamine and oleic acid (10% v/v each) in n-hexane or toluene stabilized the GaN nanocrystals as a colloidal solution. After removal of the remaining solids by centrifugation, GaN nanocrystals were flocculated with ethanol from colloidal solution and redispersed in fresh n-hexane or methylcyclohexane.

While GaN nanorods and nanotetrapods were formed regardless of ammonia pressure, a clear difference between the reaction products synthesized using ambient-pressure ammonia and high-pressure ammonia was observed in PXRD patterns and in absorption spectra (FIGS. 5A-5B). Generally, the diameter of GaN nanorods and nanotetrapods increased as the ammonia pressure increased. As ammonia pressure increased, the excitonic transitions in the absorption spectra of GaN nanorods also shifted to longer wavelengths, as expected for reduced quantum confinement effects for larger nanorod diameters (FIG. 5A). Furthermore, PXRD peaks became significantly narrower at higher ammonia pressures (FIG. 5B). This trend agreed with the simulated PXRD patterns of WZ-GaN nanorods with different thicknesses (FIG. 5E). PXRD patterns of high-pressure reaction products also showed a more intense peak [1 0 1̅ 1] compared to [1 0 1̅ 0] the peak. The simulations suggest that stacking faults can decrease the intensity ratio of [1 0 1̅ 1] to [1 0 1̅ 0] (FIG. 5F), and a stronger [1 0 1̅ 1] peak may imply that WZ-GaN nanocrystals synthesized at high ammonia pressure have fewer stacking faults. GaN nanocrystals synthesized at high ammonia pressure also yielded TEM images of higher contrast compared to the materials synthesized at an ambient pressure (FIG. 5C). PDF analysis further confirmed the formation of highly crystalline GaN (data not shown). It is notable that the PDF of GaN nanorods synthesized with high-pressure ammonia exhibited oscillation of greater amplitude to longer distances (around 7 nm) than did that of GaN nanorods synthesized with atmospheric-pressure ammonia (out to around 5 nm) (FIG. 5G). The period of these oscillations was also 0.26 nm, indicating elongation of WZ nanocrystals along direction.

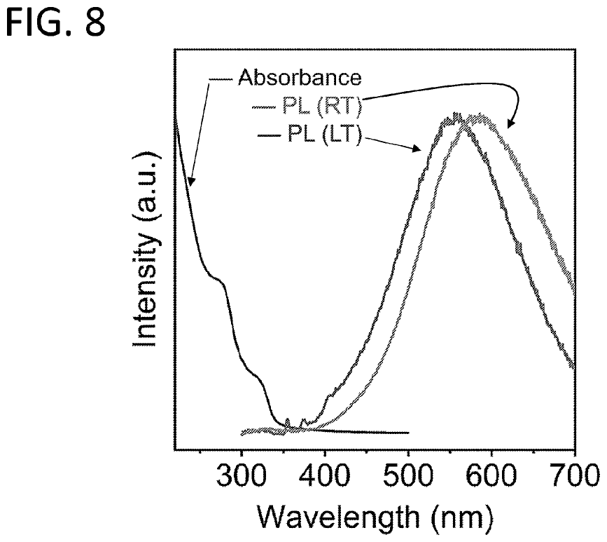

Upon excitation at 270 nm, colloidal GaN nanorods synthesized at 5 MPa ammonia pressure showed a broad band of trap emission centered around 580 nm (FIG. 5D). The photoluminescence excitation (PLE) spectra confirmed that this trap emission originated from the particles. PLE measured at different emission wavelengths indicated that the product consisted of nanocrystals of different absorption profiles and that thicker particles showed redder trap emission. The photoluminescence at low temperatures (77 K) from the same nanorods was also dominated by trap emission, with the emission band blue shifted by ~15 nm (FIG. 8).

It is believed that prior to the demonstration in this Example, controlling ammonia pressure has not previously been used for solution synthesis of III-nitride nanomaterials. This Example shows that such pressure control can be useful in GaN synthesis, as the size of the reaction products, and correspondingly size-dependent electronic structure due to quantum confinement of electronic states, can be successfully varied by controlling ammonia pressure. Growing larger particles also provides advantages for shell growth and other post-synthetic modifications, film deposition, electronic and optoelectronic properties, and other material characteristics.

### CONCLUSION

It was found that an inclusion of a molten salt phase into solution synthesis enabled formation of crystalline GaN and AlN nanoparticles at mild temperatures. In the case of GaN, nanocrystals with different crystal phases and shapes were obtained, depending on the precursor. It was further demonstrated that high pressure ammonia increased the diameter of nanorods and improved their crystallinity. It is believed that the molten salt phase provides a medium which is capable of stabilizing charged species generated during monomer detachment step, which facilitates microscopic reversibility and enables crystallization. The present methods are applicable to nanocrystals of III-nitrides in general as well as other materials.

Additional data, figures, and information, including that referenced as “not shown”, may be found in U.S. Application No. 63/399,788, filed Aug. 22, 2022, which is hereby incorporated by reference in its entirety.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” means “one or more.”

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

The foregoing description of illustrative embodiments of the disclosure has been presented for purposes of illustration and of description. It is not intended to be exhaustive or to limit the invention to the precise form disclosed, and modifications and variations are possible in light of the above teachings or may be acquired from practice of the disclosure. The embodiments were chosen and described in order to explain the principles of the disclosure and as practical applications of the invention to enable one skilled in the art to utilize the disclosure in various embodiments and with various modifications as suited to the particular use contemplated. It is intended that the scope of the disclosure be defined by the claims appended hereto and their equivalents.

What is claimed is:

1. A method of synthesizing III-V nanocrystals, the method comprising exposing a biphasic mixture comprising a molten salt phase and an organic liquid phase to a group V precursor comprising a group V element under conditions to form a III-V compound in the form of nanocrystals, wherein the molten salt phase comprises a group III precursor comprising a group III element, and the organic liquid phase comprises an organic solvent.

2. The method of claim 1, wherein the group III element is selected from Ga and Al.

3. The method of claim 1, wherein the group III precursor has formula MX₃ or formula AMX₄, wherein M is the group III element, X is a halogen, and A is an alkali metal.

4. The method of claim 1, wherein the molten salt phase consists of the group III precursor.

5. The method of claim 1, wherein the organic solvent has a boiling point of greater than 100° C.

6. The method of claim 1, wherein the organic solvent is an alkylamine.

7. The method of claim 1, wherein the group V element is nitrogen.

8. The method of claim 7, wherein the group V precursor is ammonia or a conjugate base thereof.

9. The method of claim 1, wherein the group III precursor is present in the biphasic mixture at a concentration of greater than 0.5 M.

10. The method of claim 9, wherein the concentration is at least 1 M.

11. The method of claim 1, wherein the biphasic mixture comprises at least 90 weight % of the organic liquid phase.

12. The method of claim 1, wherein the conditions comprise a temperature of greater than a melting temperature of the molten salt phase or a component thereof, and less than 400° C.

13. The method of claim 12, wherein the temperature is in a range of from 100° C. to 350° C.

14. The method of claim 1, wherein the group V precursor is ammonia at a pressure in a range of from 1 MPa to 5 MPa.

15. The method of claim 1, wherein the group III precursor is a Ga precursor, an Al precursor, or a combination thereof, and the group V precursor is a N precursor.

16. The method of claim 1, wherein the group III precursor is present in the biphasic mixture at a concentration of greater than 0.5 M and wherein the biphasic mixture comprises at least 90 weight % of the organic liquid phase.

17. The method of claim 16, wherein the molten salt phase consists of the group III precursor.

18. The method of claim 16, wherein the group III precursor has formula MX₃ or formula AMX₄, wherein M is the group III element, X is a halogen, and A is an alkali metal.

19. The method of claim 18, wherein the organic solvent is an alkylamine and the group V precursor is ammonia.

20. The method of claim 1, wherein the biphasic mixture, the molten salt phase, the organic liquid phase, the group III precursor, and the group V precursor are all free of oxygen.
